(19) United States
(12) Patent Application Publication
(10) Pub. No.: US 2008/0224914 A1
(43) Pub. Date: Sep. 18, 2008

(54) Integrated Circuit for Analog-to-Digital Conversion

(75) Inventors: Takahiro Kawashima, Ota-shi (JP); Shinji Kurihara, Ota-shi (JP)

Correspondence Address: SoCAL IP LAW GROUP LLP, 310 N. WESTLAKE BLVD. STE 120, WESTLAKE VILLAGE, CA, 91362, US

(73) Assignees: Sanyo Electric Co., Ltd., Osaka (JP); Sanyo Semiconductor Co., Ltd., Ora-gun (JP)

(21) Appl. No.: 12/048,955

(22) Filed: Mar. 14, 2008

(30) Foreign Application Priority Data
Mar. 14, 2007 (JP) 2007-065578

(51) Int. Cl. H03M 1/34; G01J 1/44

(52) U.S. Cl. 341/158; 250/206

(57) ABSTRACT

An integrated circuit for analog-to-digital conversion for performing digital conversion of the amount of current of an input current and outputting a digital signal, comprises: a resistor connection terminal to be connected to a resistor; a conversion section configured to convert the amount of current of the input current or the amount of current of a reference current flowing through the resistor into a digital signal to be output; and a compensation section configured to compensate the digital signal corresponding to the input current based on the digital signal corresponding to the reference current.

### CROSS-REFERENCE TO RELATED APPLICATION

This application claims the benefit of priority to Japanese Patent Application No. 2007-65578, filed Mar. 14, 2007, of which full contents are incorporated herein by reference.

### BACKGROUND OF THE INVENTION

1. Field of the Invention

The present invention relates to an integrated circuit for analog-to-digital conversion.

2. Description of the Related Art

A liquid crystal display is used for various kinds of equipment such as cellular phone, laptop computer and so on. Such a LCD is generally built to have a back light provided on the back side of the liquid crystal panel. A liquid crystal display having a back light detects an ambient brightness of the equipment using an illuminance sensor having a light receiving element such as photo diode and adjusts the luminance of the back light based on the detected illuminance. This type of an illuminance sensor is often provided as an integrated circuit, in which an analog signal corresponding to the amount of the current generated by a light receiving element is converted into a digital signal by a delta-sigma-modulated AD converter, thereby outputting the detection result of illuminance (e.g. Japanese Unexamined Patent Application Publication No. 2005-283248).

A delta-sigma-modulated AD converter, for example, is generally constructed to include an integrating circuit or an oscillation circuit. Such an A-D converter will incur the reduced accuracy of outputted digital signal due to variable capacity of the capacitor constituting the integrating circuit or variable oscillation signals generated by the oscillation circuit. The reduction in conversion accuracy in the A-D converter will result in the degradation in the accuracy of the detection results of illuminance with the illuminance sensor.

The present invention has been made considering the above-mentioned problems and an objection of the present invention is to provide an integrated circuit for analog-to-digital conversion in which the influence from a variation of performance in an integrated circuit can be reduced.

### SUMMARY OF THE INVENTION

An integrated circuit for analog-to-digital conversion for performing digital conversion of the amount of current of an input current and outputting a digital signal according to an aspect of the present invention, comprises: a resistor connection terminal to be connected to a resistor; a conversion section configured to convert the amount of current of the input current or the amount of current of a reference current flowing through the resistor into a digital signal to be output; and a compensation section configured to compensate the digital signal corresponding to the input current based on the digital signal corresponding to the reference current.

Other features of the present invention will become apparent from descriptions of this specification and of the accompanying drawings.

### BRIEF DESCRIPTION OF THE DRAWINGS

For more thorough understanding of the present invention and advantages thereof, the following description should be read in conjunction with the accompanying drawings, in which:

FIG. 1 is a block diagram of a mobile terminal built to include an illuminance sensor which constitutes an embodiment of the present invention;

FIG. 2 is a block diagram of an illuminance sensor of the embodiment; and

FIG. 3 is an example of variation in an output X of an operational amplifier.

### DETAILED DESCRIPTION OF THE INVENTION

At least the following details will become apparent from descriptions of this specification and of the accompanying drawings.

==Configuration==

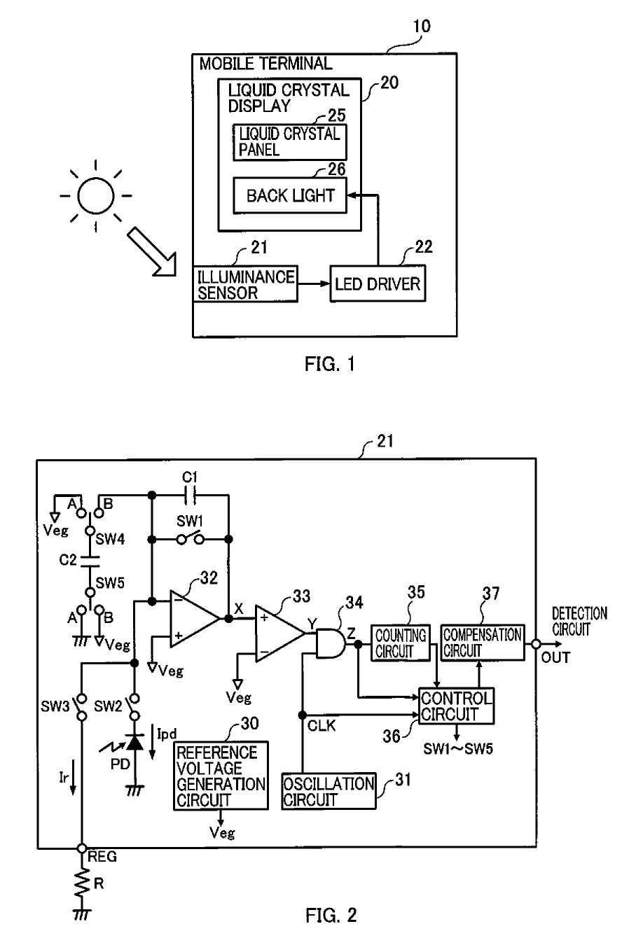

FIG. 1 illustrates a block diagram of a mobile terminal built to include an illuminance sensor which constitutes an embodiment of the present invention. A mobile terminal 10 is constructed to comprise a liquid crystal display 20, an illuminance sensor 21 and an LED driver 22.

The liquid crystal display 20 is a device that serves to provide a variety of textual and visual information for a user of the mobile terminal 10 in a viewable manner, and is constructed including a liquid crystal display panel 25 and a back light 26. The liquid crystal display 20 displays by emitting light from the back light 26 provided on the back of the liquid crystal display panel 25 instead of emitting light from the liquid crystal display 25 itself. Thus the adjustment of the brightness of the liquid crystal display 20 is accomplished by adjusting the brightness of the back light 26. This embodiment of the present invention uses LEDs (Light Emitting Diodes) for the back light 26, however, light emitting elements other than LEDs may be used.

The illuminance sensor 21 is a circuit that serves to detect illuminance which shows the ambient brightness of the mobile terminal 10, and outputs the voltage or current increased/decreased corresponding to the illuminance as a detection result.

The LED driver 22 adjusts the luminance of the LEDs which constitutes the back light 26 based on the detection result of the illuminance outputted by the illuminance sensor 21. That is, when the ambient brightness of the mobile terminal 10 is low, the luminance of the back light 26 is reduced because a low brightness of the display does not reduces the visibility. To the contrary, when the ambient brightness of the mobile terminal 10 is high, the luminance of the back light 26 is increased because a low brightness of the display reduces the visibility of the display.

FIG. 2 illustrates a block diagram of the illuminance sensor 21 of this embodiment. The illuminance sensor 21 is an integrated circuit comprised of a reference voltage generation circuit 30, an oscillation circuit 31, an operational amplifier 32, a comparator 33, an AND circuit 34, a counting circuit 35, a control circuit 36, a compensation circuit 37, a photo diode PD, capacitors C1, C2, switches SW1 to SW5, a connection terminal REG and an output terminal OUT. A delta-sigma modulation type A-D converter (an integrated circuit for analog-to-digital conversion) has the same configuration as that of the illuminance sensor 21, excluding the photo diode PD. A circuit comprising the reference voltage generation circuit 30, the oscillation circuit 31, the operational amplifier 32, the comparator 33, the AND circuit 34, the counting circuit 35, the control circuit 36, the capacitors C1, C2 and the switches SW1 to SW5 is equivalent to a conversion section of the present invention.

The photo diode PD (light receiving element) generates current Ipd corresponding to the amount of incident light if the switch SW2 is on. Since a resistor R having a resistance of R is connected to the connection terminal REG, reference current Ir (=Veg/R) flows through the resistor R if the switch SW3 is on. Since the resistor R is provided externally to the illuminance sensor 21 which constitutes the integrated circuit, it is less variable than circuits such as registers which are internally used in the illuminance sensor 21, and accordingly has a higher accuracy of resistance.

The reference voltage generation circuit 30 comprises using a band gap circuit, for example, and generates reference voltage Veg at a given level. The oscillation circuit 31 generates clock CLK oscillating at a given frequency.

The operational amplifier 32 and the capacitor C1 constitute an integrating circuit to integrate the current Ipd or the reference current Ir. That is, if the switch SW2 is on and the switch SW3 is off, the value of the voltage of the output X from the operational amplifier 32 is obtained by integrating the current Ipd. On the other hand, if the switch SW2 is off and the switch SW3 is on, the value of the voltage of the output X from the operational amplifier 32 is obtained by integrating the reference current Ir.

The capacitor C2 serves to discharge an accumulated electric charge from the capacitor C1. If the capacity of the capacitors C1 and C2 is C, an electric charge [C×Veg] is accumulated in the capacitor C2 while the switches SW4 and SW5 are connected to side A. If the switches SW4 and SW5 are changed over to side B, an electric charge equal to that accumulated in the capacitor C2 is discharged from the capacitor C1, thereby causing a drop in the voltage of the output X from the operational amplifier 32 by Veg.

The comparator 33 compares the voltage of the output X from the operational amplifier 32 with respect to the reference voltage Veg and outputs a signal Y indicating the comparison result. With this embodiment, the signal Y is provided at a Low level if the voltage of the output X from the operational amplifier 32 is less than the reference voltage Veg; it is provided at a High level if the voltage of the output X from the operational amplifier 32 is not less than the reference voltage Veg.

The AND circuit 34 serves to generate a pulse indicating that the voltage of the output X from the operational amplifier 32 exceeds the reference voltage Veg based on the output of the comparator 33, and outputs a logical multiplication of the output signal Y of the comparator 33 and the clock CLK.

The counting circuit 35 serves to count and output the number of pulses output from the AND circuit 34. The control circuit 36 (digital signal output section) serves to convert the current Ipd or the reference current Ir into a digital signal by controlling the switches SW1 to SW5 based on the pulses output from the AND circuit 34 and the clock CLK.

The compensation circuit 37 serves to compensate for the digital signal indicating the amount of current of the current Ipd based on the digital signal indicating the amount of current of the reference current Ir detected by the control circuit 36 and output the compensated signal. A theoretical digital signal Dr is assumed, for example, which indicates the amount of current of the reference current Ir if there is no variation in the capacitors C1 and C2 and the clock CLK within the illuminance sensor 21. It is further assumed that the digital signal indicating the amount of current of the reference current Ir (=Veg/R) actually detected by the control circuit 36 is Dr′ and the digital signal indicating the amount of current of the current Ipd is Dpd. In this case, the compensation circuit 37 compensates the digital signal Dpd based on the difference between the digital signal Dr and the digital signal Dr′ and outputs the compensated signal.

==Operation==

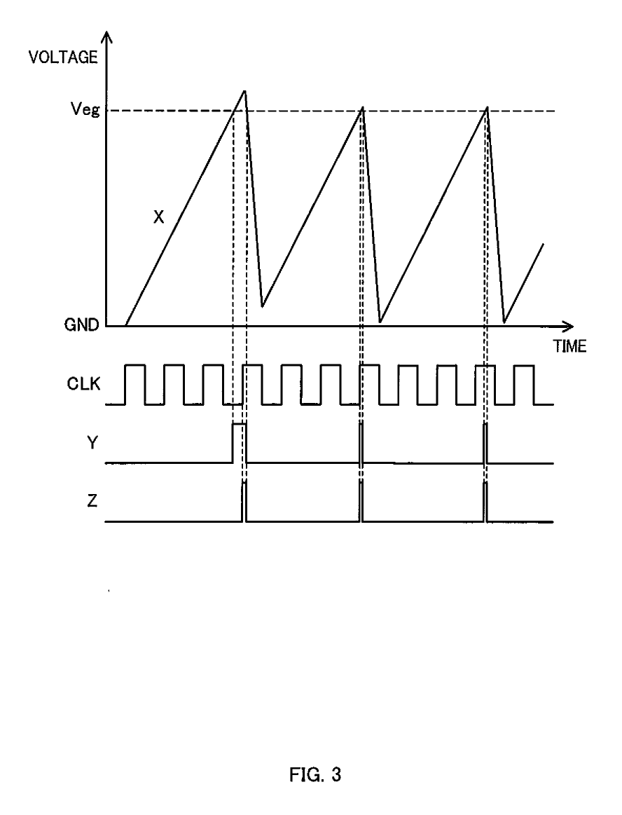

The detection processing of illuminance in the illuminance sensor 21 is described next. FIG. 3 illustrates changes in the output X of the operational amplifier 32. First of all, the control circuit 36 turns on/off the switch SW1 to discharge the capacitor C1. The control circuit 36 then turns off the switch SW2 and turns on the switch SW3 and connects the switches SW4 and SW5 to the side A. This rises up the voltage of the output X from the operational amplifier 32 corresponding to the reference current Ir (=Veg/R), as shown in FIG. 3. When the voltage of the output X has exceeded the reference voltage Veg, the output signal Y from the comparator 33 becomes a High level. Once the output Y becomes a High level, the output Z of the AND circuit 34 becomes a High level while the clock CLK is provided at a High level.

When the output from the AND circuit 34 has become a High level, the control circuit 36 changes over the switches SW4 and SW5 to the side B. With the switches SW4 and SW5 changed over to the side B, an electric charge in the capacitor C1 is discharged and the voltage of the output X from the operational amplifier 32 drops by Veg. When the voltage of the output X from the operational amplifier 32 decreases and becomes lower than the reference voltage Veg, the output Y from the comparator 33 becomes a Low level, thereby causing the output Z of the AND circuit 34 to become a Low level.

Once the output Z of the AND circuit 34 has become a Low level, the control circuit 36 changes over the switches SW4 and SW5 to the side A. This makes the output X of the operational amplifier 32 start increasing again. The repetition of such operations causes the AND circuit 34 to generate pulses at an interval corresponding to the amount of current of the reference current Ir. Therefore the control circuit 36 detects a value counted by the counting circuit 35 during a given period of time T0 calculated by the clock CLK which is outputted from the oscillation circuit 31, as a digital signal Dr′ indicating the amount of current of the reference current Ir.

Then the control circuit 36 turns on/off the switch SW1 and discharge the capacitor C1. Next, the control circuit 36 turns on and off the switches SW2 and SW3, respectively, and connects the switches SW4 and SW5 to the side A. When the similar operation to that for detecting the digital signal Dr′ indicating the reference current is performed, the AND circuit 34 generates pulses at an interval corresponding to the amount of current of the current Ipd. The control circuit 36 then detects a value counted by the counting circuit 35 during a given period of time T1 calculated by the clock CLK which is outputted from the oscillation circuit 31, as a digital signal Dpd indicating the amount of current of the reference current Ipd.

The compensation circuit 37 compensates the digital signal Dpd indicating the amount of current of the current Ipd based on the theoretical digital signal Dr indicating the amount of current of the reference current Ir in the case where there is no variation in the capacitors C1, C2 and the clock CLK, and also on the digital signal Dr′ which has been detected by the control circuit 36, and outputs the compensated signal. For example, if the value of the digital signal Dr is 128 and that of the digital signal Dr′ is 120, the compensation circuit 37 adds by 8 counts per 120 counts to the value of the digital signal Dpd detected by the control circuit 36, and outputs the compensated signal. For example, if the value of the digital signal is 128 and that of the digital signal Dr′ is 131, the compensation circuit 37 subtracts by 3 counts per 131 counts from the value of the digital signal Dpd detected by the control circuit 36, and outputs the compensated signal.

Provided above is the description of this embodiment. As stated above, the illuminance sensor 21 detects the digital signal Dr′ indicating the amount of current of the reference current Ir which flows through the resistor R externally connected to the illuminance sensor 21, and compensates the digital signal Dpd indicating the amount of current of the current Ipd based on the digital signal Dr′. Therefore, an error which may be caused by the variation of the capacitors C1 and C2 and the clock CLK can be detected by utilizing the resistor R which is less variation than elements within the integrated circuit and has high accuracy in resistance. Then the influence from the variation of performance in the integrated circuit can be decreased by compensating the digital signal Dpd indicating the amount of current of the current Ipd based on the detected error.

In the illuminance sensor 21 which uses the clock CLK, for example, for delta-sigma modulation, variation of a resistor or a capacitor constituting the oscillation circuit 31 may cause variation in the frequency of the clock CLK. The influence of variation in the clock CLK in the integrated circuit can be reduced by detecting an error using the resistor R with less variation.

In digital sigma modulation, because an integral quantity of a given time measured by the clock CLK is signalized, the faster the clock CLK runs, the shorter the given time becomes, and vice versa. Accordingly, as a given time measured by the clock CLK changes, an integral quantity of the given time changes. In the illuminance sensor 21 according to this embodiment, the influence of the variation of the clock CLK can be reduced by detecting an error using the resistor R with less variation and compensating the digital signal based on the detected error.

The above embodiments of the present invention are simply for facilitating the understanding of the present invention and are not in any way to be construed as limiting the present invention. The present invention may variously be changed or altered without departing from its spirit and encompass equivalents thereof.

According to this embodiment, for example, a photo diode is used as a light receiving element, and however, any element which generates current corresponding to the amount of incident light may be used instead of the photo diode. An element having the similar function to that of a control circuit 36 or compensation circuit 37 may be constituted by means of software control, for example.

What is claimed is:

1. An integrated circuit for analog-to-digital conversion for performing digital conversion of the amount of current of an input current and outputting a digital signal, comprising:
a resistor connection terminal to be connected to a resistor;
a conversion section configured to convert the amount of current of the input current or the amount of current of a reference current flowing through the resistor into a digital signal to be output; and
a compensation section configured to compensate the digital signal corresponding to the input current based on the digital signal corresponding to the reference current.

2. The integrated circuit for analog-to-digital conversion according to claim 1, wherein
the conversion section includes:
a reference voltage generation circuit configured to generate the reference voltage;
an integrating circuit configured to output an integration result obtained by integrating the input current or the reference current;
a comparison circuit configured to output a comparison result obtained by comparing between the integration result and the reference voltage; and
a digital signal output section configured to control the integrating circuit based on the comparison result and output the digital signal corresponding to the input current or the reference current.

3. The integrated circuit for analog-to-digital conversion according to claim 2, wherein
the conversion section further includes an oscillation circuit configured to output an oscillation signal at a given frequency, and outputs the digital signal corresponding to the input current or the reference current based on the comparison result and the oscillation signal.

4. The integrated circuit for analog-to-digital conversion according to claim 1, further comprising
a light receiving element configured to generate the input current corresponding to the amount of incident light.

5. The integration circuit for analog-to-digital conversion according to claim 2, further comprising
a light receiving element configured to generate the input current corresponding to the amount of incident light.

6. The integrated circuit for analog-to-digital conversion according to claim 3, further comprising
a light receiving element configured to generate the input current corresponding to the amount of incident light.
